(19) United States
(12) Patent Application Publication
(10) Pub. No.: US 2002/0099989 A1
(43) Pub. Date: Jul. 25, 2002

(54) Automatic circuit generation system and automatic circuit generation method and automatic circuit generation program

(76) Inventors: Naoyuki Kawabe, Kanagawa-ken (JP); Kimiyoshi Usami, Kanagawa-ken (JP); Takeshi Kitahara, Kanagawa-ken (JP)

Correspondence Address: GARY CARY WARE & FREIDENRICH, 1755 EMBARCADERO, PALO ALTO, CA, 94303-3340, US

(21) Appl. No.: 10/056,426

(22) Filed: Jan. 23, 2002

(30) Foreign Application Priority Data
Jan. 23, 2001 (JP) P2001-14340

(51) Int. Cl. G01R 31/28; G11C 7/00

(52) U.S. Cl. 714/724; 365/200

(57) ABSTRACT

An automatic circuit generation system for generating an object circuit by the use of a cell library including logic cells is described. The system comprising a node state analyzing unit which is configured to obtain combinations of input signals to exchangable input pins of a logic cell of the cell library included in the object circuit and the probabilities of the respective combinations of the input signals; a leakage current estimating unit which is configured to determine a combination of the input signals, with which the leakage current passing through the logic cell of the cell library included in the object circuit is minimized, with reference to information about leakage currents passing through the exchangable input pins of the logic cell of the cell library included in the object circuit; and an output unit which is configured to output circuit information in accordance with the combination of the input signals as obtained by the leakage current estimating unit.

### CROSS REFERENCE TO RELATED APPLICATIONS

This application is based upon and claims the benefit of priority from prior Japanese Patent Application P2001-14340 filed on Jan. 23, 2001; the entire contents of which are incorporated by reference herein.

### BACKGROUN OF THE INVENTION

1. Field of the Invention

The present invention relates to an automatic circuit generation system, an automatic circuit generation method and an automatic circuit generation program.

2. Description of the Related Art

Recently, because of the miniatuarization and the low voltage operation of LSI chips, the threshold voltages (Vth) of the constituent transistors as designed are constantly lowered. As the threshold voltage is lowered, subthreshold leakage currents tend to be increased. The leakage currents are always passed through the circuit when the circuit is either inactivated in a standby state or activated in a normal state. Accordingly, the leakage currents are even more problematic in the application of such transistors to mobile phones or mobile terminals and so forth in which the leakage currents become a significant factor of shortening the lifetime of a battery.

In accordance with the conventional techniques, the Dual Vth approach has been proposed as a solution of the leakage currents. The Dual Vth approach makes use of both a cell library including low Vth cells composed of transistors with low threshold voltages and a cell library including high Vth cells composed of transistors with high threshold voltages for designing the same logic circuit. Namely, the leakage currents are suppressed by the use of low speed high Vth cells in current paths where ample timing margins are given while high speed low Vth cells are used to meet strict timing requirements in other current paths.

There are following procedures of generating circuit designs in accordance with the above approach.

(1) After generating the entirety of a circuit design by the use of high speed low Vth cells, low speed high Vth cells are used to substitute for some low Vth cells located in current paths, where ample timing margins are given, as many as the timing requirements permit.

(2) After generating the entirety of a circuit design by the use of low speed high Vth cells, high speed low Vth cells are used to substitute for some high Vth cells located in current paths where timing requirements are not satisfied until all the timing requirements are satisfied.

On the other hand, the amount of a leakage current passing through a cell of the logic circuit depends on the combination of the input signals to the cell of the logic circuit. For example, in a 2-input NAND gate of a CMOS structure as illustrated in FIG. 1, the value of the leakage current is relatively small when the input signals are such that (A, B)=(0, 0) because the leakage current is passed through two NMOS transistors (N-channel transistors) N1 and N2 which are connected in series and turned off as illustrated in FIG. 2. On the other hand, the value of the leakage current is relatively large when the input signals are such that (A, B)=(1, 1) because the leakage current is passed through two PMOS transistors (P-channel transistors) P1 and P2 which are connected in parallel and turned off. In the case where the input signals are such that (A, B)=(1, 0) or (A, B)=(0, 1), the leakage current is passed through one NMOS transistor which is turned off. However, the drain voltage of the lower NMOS transistor N2 is lowered by the threshold voltage of the upper NMOS transistor N1 in the case where the input signals are such that (A, B)=(1, 0). By this configuration, the voltage between the source and the drain of the lower NMOS transistor N2 is reduced by the threshold voltage of the upper NMOS transistor N1 and therefore the leakage current is decreased by the reduction.

On the other hand, in the case where the input signals are such that (A, B)=(0, 1), no current is passed through the lower NMOS transistor N2 so that the source voltage of the upper NMOS transistor N1 is pulled down to “0”. Accordingly, the voltage between the source and the drain of the lower NMOS transistor N2 is maintained at the power voltage Vdd and therefore the leakage current becomes large as compared with the case where the input signals are such that (A, B)=(1, 0).

Namely, in accordance with the conventional technique, necessary consideration is not involved in the effort to effectively reduce the leakage currents while the value of a leakage current passed through a logic circuit is depending on the input signals as described above.

### BRIEF SUMMARY OF THE INVENTION

An aspect of the present invention provides an automatic circuit generation system comprising:

a processing unit which is configured to receive circuit generation information required for generating a circuit, and analyzing the circuit generation information as received to generate circuit connection data and leakage current data;

an analyzing unit which is configured to receive test vectors which are used as input signals for operating the circuit, operating a circuit with the test vectors, obtaining the state(s) of each node and the probability of each state of each node as occurs in the circuit;

a leakage current estimating and input signal exchanging unit which is configured to receive said circuit generation information and the state(s) of each node and the probability of each state of each node as obtained by said analyzing unit, calculating the leakage currents of the circuit, calculating the leakage currents of the circuit in the cases where input signals to exchangable pins of the circuit are exchanged, and determining an assignment of the input signals to the exchangable pins corresponding to minimum values of the leakage currents; and

an output unit which is configured to output the netlist of the circuit in which the exchangable pins of the circuit are assigned to the input signals as generated the assignment as determined by said leakage current estimating and input signal exchanging unit.

Another aspect of the present invention provides an automatic circuit generation method comprising:

receiving circuit generation information required for generating a circuit, and analyzing the circuit generation information as received to generate circuit connection data and leakage current data;

receiving test vectors which are used as input signals for operating the circuit, operating a circuit with the test vectors, obtaining the state(s) of each node and the probability of each state of each node as occurs in the circuit;

receiving said circuit generation information and the state(s) of each node and the probability of each state of each node as obtained, calculating the leakage currents of the circuit, calculating the leakage currents of the circuit in the cases where input signals to exchangable pins of the circuit are exchanged, and determining an assignment of the input signals to the exchangable pins corresponding to minimum values of the leakage currents; and

outputting the netlist of the circuit in which the exchangable pins of the circuit are assigned to the input signals as generated the assignment as determined.

A further aspect of the present invention provides an automatic circuit generation program embodied on a computer-readable medium for generating circuits, said program comprising:

receiving circuit generation information required for generating a circuit, and analyzing the circuit generation information as received to generate circuit connection data and leakage current data;

receiving test vectors which are used as input signals for operating the circuit, operating a circuit with the test vectors, obtaining the state(s) of each node and the probability of each state of each node as occurs in the circuit;

receiving said circuit generation information and the state(s) of each node and the probability of each state of each node as obtained, calculating the leakage currents of the circuit, calculating the leakage currents of the circuit in the cases where input signals to exchangable pins of the circuit are exchanged, and determining an assignment of the input signals to the exchangable pins corresponding to minimum values of the leakage currents; and

outputting the netlist of the circuit in which the exchangable pins of the circuit are assigned to the input signals as generated the assignment as determined.

A further aspect of the present invention provides an automatic circuit generation system for generating an object circuit by the use of a cell library including logic cells, said system comprising:

a node state analyzing unit which is configured to obtain combinations of input signals to exchangable input pins of a logic cell of said cell library included in said object circuit and the probabilities of the respective combinations of the input signals;

a leakage current estimating unit which is configured to determine a combination of the input signals, with which the leakage current passing through said logic cell of said cell library included in said object circuit is minimized, with reference to information about leakage currents passing through the exchangable input pins of said logic cell of said cell library included in said object circuit; and

an output unit which is configured to output circuit information in accordance with the combination of the input signals as obtained by said leakage current estimating unit.

A further aspect of the present invention provides an automatic circuit generation program embodied on a computer-readable medium for generating an object circuit by the use of a cell library including logic cells, said program comprising:

obtaining combinations of input signals to exchangable input pins of a logic cell of said cell library included in said object circuit and the probabilities of the respective combinations of the input signals;

determining an optimum combination of the input signals, with which the leakage current passing through said logic cell of said cell library included in said object circuit is minimized, with reference to information about leakage currents passing through the exchangable input pins of said logic cell of said cell library included in said object circuit; and

outputting circuit information in accordance with the optimum combination of the input signals as obtained with which the leakage current passing through said logic cell of said cell library included in said object circuit is minimized.

### BRIEF DESCRIPTION OF THE DRAWINGS

FIG. 1 is a circuit diagram showing a 2-input NAND gate.

FIG. 2 is a table showing examples of the leakage currents applicable to the 2-input NAND gate as illustrated in FIG. 1.

FIG. 3 is a schematic diagram showing an automatic circuit generation system in accordance with an embodiment of the present invention.

FIG. 4 is a flowchart showing the automatic circuit generation method in accordance with the embodiment of the present invention as illustrated in FIG. 3.

FIG. 5 is a circuit diagram showing a 3-input NAND gate.

FIG. 6 is a table showing examples of the leakage currents applicable to the 3-input NAND gate as illustrated in FIG. 5.

FIG. 7 is a circuit diagram showing the 3-input NAND gate as generated by the automatic circuit generation system as illustrated in FIG. 3.

FIG. 8 is a schematic diagram showing the appearance of the automatic circuit generation system in accordance with the embodiment of the present invention.

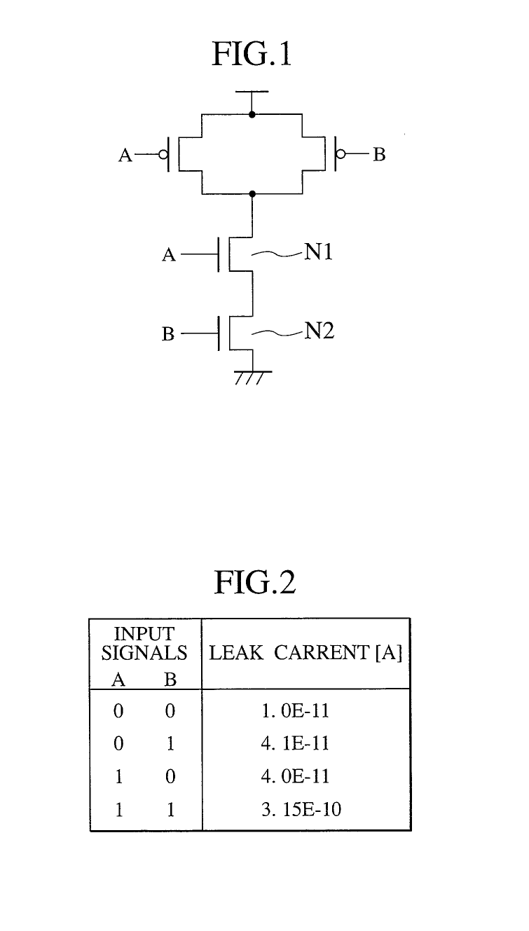

### DETAILED DESCRIPTION OF THE INVENTION

In the followings, an embodiments of the present invention will be described with reference to the accompanying drawings.

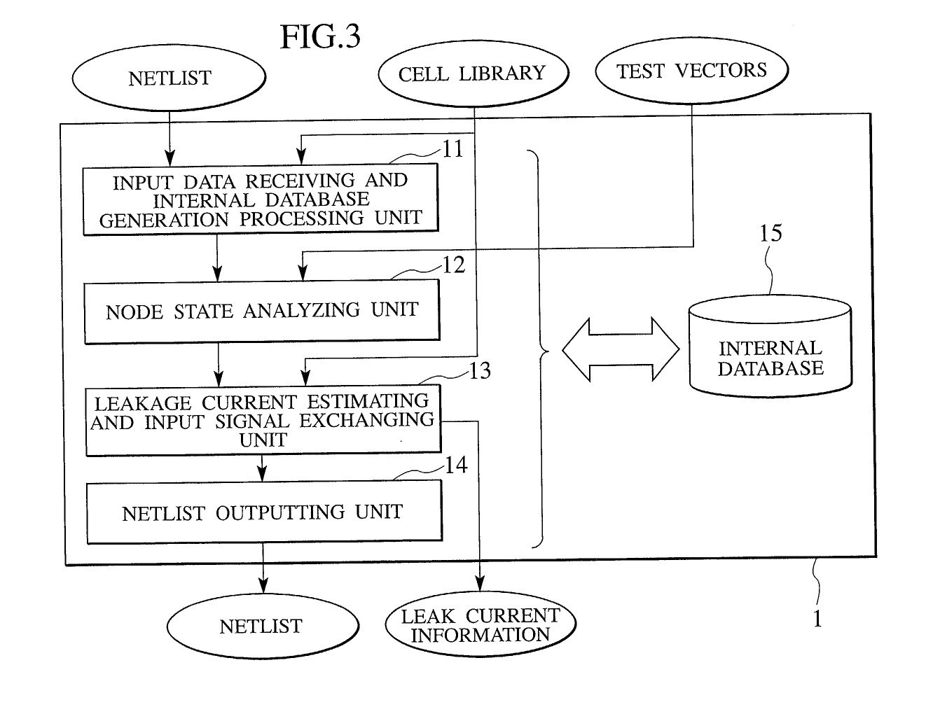

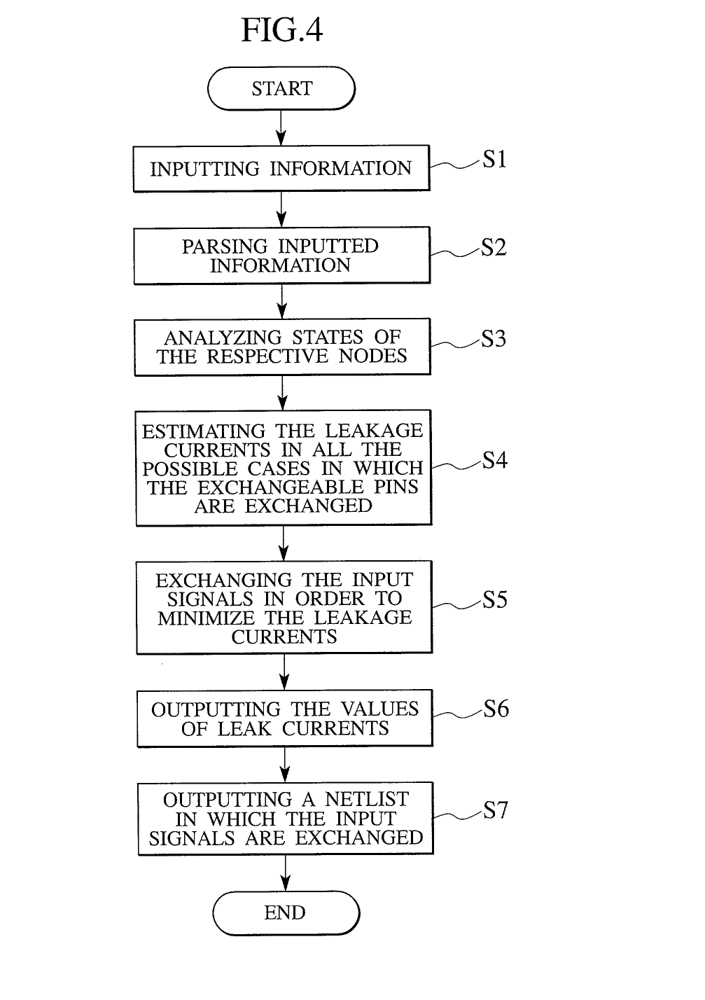

FIG. 3 is a schematic diagram showing an automatic circuit generation system in accordance with the embodiment of the present invention. FIG. 4 is a flowchart showing the automatic circuit generation method in accordance with the embodiment of the present invention.

The automatic circuit generation system is composed of an input data receiving and internal database generation processing unit 11 for receiving input data such as gate level netlists, cell libraries and so forth, a node state analyzing unit 12 for obtaining the state(s) of each node (each input terminal of the respective cells) and the probability of each state of each node as occurs in the logic circuit, a leakage current estimating and input signal exchanging unit 13 for estimating the values of leakage currents passing through the respective cells and exchanging the input signals to the respective nodes in order to minimize the values of the leakage currents on the basis of the estimation, a netlist outputting unit 14 for outputting the netlist in which input signals have been exchanged in order to minimize the values of the leakage currents, and an internal database 15 in which are registered the circuit connection data and the leakage current data as obtained. Meanwhile, the values of the leakage currents may be provided together with the cell libraries in advance. Generally speaking, while the values of the leakage currents can be calculated with reference to the circuit designs and patterns of the respective cells and so forth, more accurate values can be obtained by measuring the actual currents passing through each circuit element.

Next, the operation of the automatic circuit generation system 1 as described above will be explained with reference to the flowchart as illustrated in FIG. 4. In FIG. 4, at first, necessary information such as gate level netlists, process parameters of the object circuit, cell libraries to be used and so forth is input to the input data receiving and internal database generation processing unit 11 in the step S1 and processed by the input data receiving and internal database generation processing unit 11 in order to obtain the circuit connection data and the leakage current data which is registered in the internal database 15 in the step S2.

Next, the node state analyzing unit 12 receives test vectors which are used as input signals for operating the circuit under test. The state(s) of each node and the probability of each state of each node as occurs in the logic circuit are obtained by operating the circuit under test with the test vectors as received with reference to the circuit connection data as registered as the internal database 15, in which the respective information as obtained is registered in the step S3. Then, on the basis of the state(s) of each node and the probability of each state of each node as obtained by the node state analyzing unit 12, the values of the leakage currents in the logic circuit are calculated by the leakage current estimating and input signal exchanging unit 13 and registered in the internal database 15. At this time, if there are exchangable pins of the input pins of each cell, the values of the leakage currents are calculated in all the possible cases in which the exchangable pins are exchanged and are registered in the internal database 15 in the step S4. In this case, exchangable pins are such pins of the input terminals of each logic circuit (in this case, each cell involved in the logic circuit) as receiving input signals which can be exchanged without any influence on the logic of the circuit. By this configuration, the input signals are exchanged in order to minimize the values of the leakage currents and are registered in the internal database 15 in the step S5. Also, the values of the leakage currents are outputted as the leakage current information in the step S6. The netlist outputting unit 14 then outputs the netlist in which the input signals are exchanged in order to minimize the values of the leakage currents in the step S7.

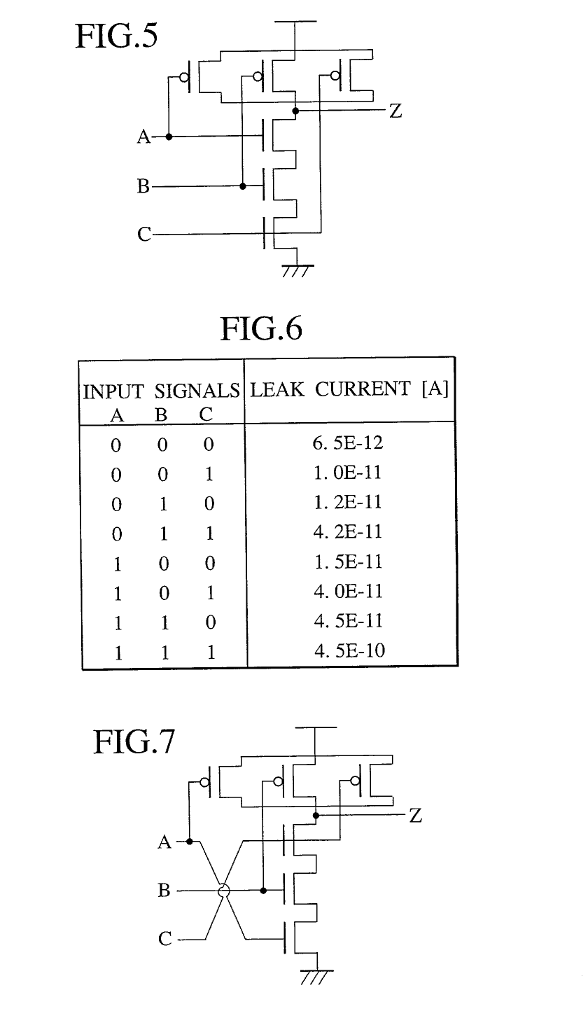

Next, the operation of the automatic circuit generation system 1 as described above will be explained in the case where the 3-input NAND gate is generated as illustrated in FIG. 5. In this case, it is assumed that the values of the leakage currents as illustrated in FIG. 6 are applicable to the logic gate as illustrated in FIG. 5.

In the case of the 3-input NAND gate as illustrated in FIG. 5 the input signals A, B and C can be exchanged without any influence on the logic thereof, i.e., symmetric as seen from the logic. Next, the logic gate is discussed when the input signals (A, B and C)=(1, 0 and 0) with which it is assumed that the logic gate is inactivated in a standby state. Since the input signals of the logic gate are symmetric, the input signals can be exchanged in any way without any influence on the logic. There are three possible cases, i.e., where the input signals (A, B and C)=(0, 1 and 0), where the input signals (A, B and C)=(1, 0 and 0) and where the input signals (A, B and C)=(0, 0 and 1) after changing assignment of the input signals to the input terminals of the logic gate. It is understood from FIG. 6 that the values of the leakage currents is minimized in the case where the input signals (A, B and C)=(0, 0 and 1). Accordingly, this case is selected as illustrated in FIG. 7.

On the other hand, when the circuit under test is operating, the input signals are dynamically changed. If it is desired to decrease the values of the leakage currents during operation, the probability of each combination of the input signals is obtained by the node state analyzing unit 12 on the basis of test vectors. The appropriate assignment of the input signals to the input terminals of the logic gate is then obtained with reference to the probability of each combination of the input signals and the values of the leakage currents corresponding to each combination in order to minimize the values of the leakage currents. For example, in the case where the probabilities of the input signals (A, B and C)=(1, 0 and 0), (0, 1 and 0) and (0, 0 and 1) are 0.5, 0.3 and 0.2 respectively, the total value of the leakage currents is calculated as 1.16×10⁻¹¹(=0.5×1.0×10⁻¹¹+0.3×1.2×10⁻¹¹+0.2×1.5×10⁻¹¹) by interchanging the input signals A and C. The probabilistic total value of the leakage currents is minimized in this case. Meanwhile, in the case where the optimal connections of the input signals of the logic circuit inactivated in a standby state is different from the optimal connections of the input signals of the logic circuit activated in a normal state, it is determined which connections is given priority and to be selected in accordance with the specification of the circuit design. Also, it is apparent to those skilled in the art that the technique as described above is applicable generally to any logic circuit having exchangable pins.

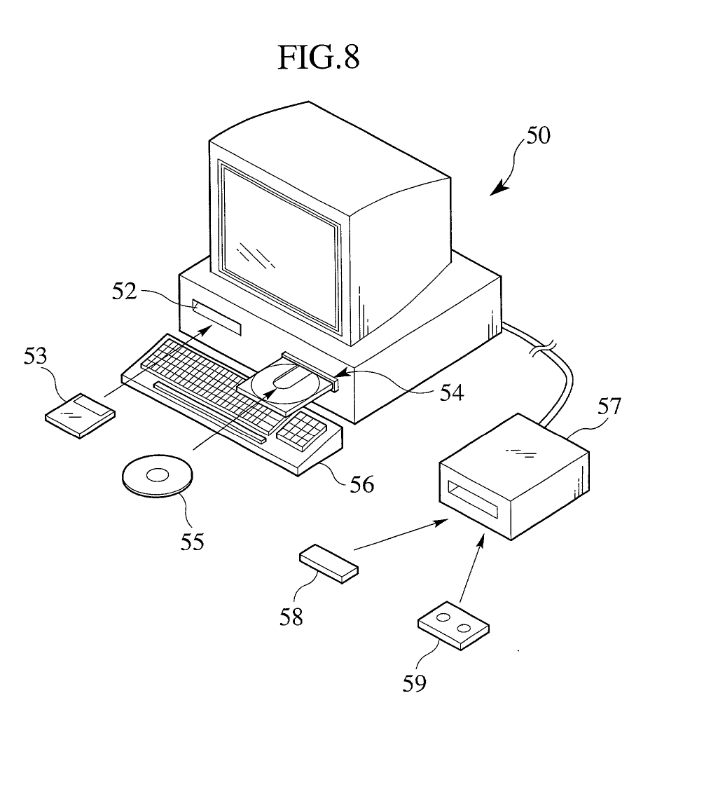

In the following description, an automatic circuit generation program will be explained. The automatic circuit generation system 1 as used in accordance with this embodiment of the present invention is implemented with a so called general-purpose machine, a workstation, a PC (Personal Computer), and an NC (Network Computer) or the like in which is installed the automatic circuit generation program in accordance with an embodiment of the present invention. This system has its appearance shown in FIG. 8, for example, and comprises a floppy disk drive 52 and an optical disk drive 54. Then, a floppy disk 53 is inserted into a floppy disk drive 52; an optical disk 55 is inserted into an optical disk drive 54; and predetermined readout operation is performed, whereby programs stored in these recording media can be installed in a computer system. In addition, a predetermined drive device 57 is connected, whereby installation or data reading and writing can be executed by using a ROM 58 that serves as a memory device or a cartridge 59 that serves as a magnetic tape. In addition, the automatic circuit generation program in accordance with the embodiments of the present invention may be stored in a computer readable recording medium. Then, in performing the automatic circuit generation, this recording medium is read by a computer system; the automatic circuit generation system is stored in a storage unit such as memory incorporated in the computer system; and the automatic circuit generation program is executed by a computing device. The recording media used here comprises a computer readable recording media capable of recording, for example, a semiconductor memory, a magnetic disk, an optical disk, a magneto-optical disk, a magnetic tape, and a transmission medium.

The foregoing description of the embodiments has been presented for purposes of illustration and description. It is not intended to be exhaustive or to limit the invention to the precise form described, and obviously many modifications and variations are possible in light of the above teaching. The embodiment was chosen in order to explain most clearly the principles of the invention and its practical application thereby to enable others in the art to utilize most effectively the invention in various embodiments and with various modifications as are suited to the particular use contemplated.

What is claimed is:

1. An automatic circuit generation system comprising:
a processing unit which is configured to receive circuit generation information required for generating a circuit, and analyzing the circuit generation information as received to generate circuit connection data and leakage current data;
an analyzing unit which is configured to receive test vectors which are used as input signals for operating the circuit, operating a circuit with the test vectors, obtaining the state(s) of each node and the probability of each state of each node as occurs in the circuit;
a leakage current estimating and input signal exchanging unit which is configured to receive said circuit generation information and the state(s) of each node and the probability of each state of each node as obtained by said analyzing unit, calculating the leakage currents of the circuit, calculating the leakage currents of the circuit in the cases where input signals to exchangable pins of the circuit are exchanged, and determining an assignment of the input signals to the exchangable pins corresponding to minimum values of the leakage currents; and
an output unit which is configured to output the netlist of the circuit in which the exchangable pins of the circuit are assigned to the input signals as generated the assignment as determined by said leakage current estimating and input signal exchanging unit.

2. An automatic circuit generation method comprising:
receiving circuit generation information required for generating a circuit, and analyzing the circuit generation information as received to generate circuit connection data and leakage current data;
receiving test vectors which are used as input signals for operating the circuit, operating a circuit with the test vectors, obtaining the state(s) of each node and the probability of each state of each node as occurs in the circuit;
receiving said circuit generation information and the state(s) of each node and the probability of each state of each node as obtained, calculating the leakage currents of the circuit, calculating the leakage currents of the circuit in the cases where input signals to exchangable pins of the circuit are exchanged, and determining an assignment of the input signals to the exchangable pins corresponding to minimum values of the leakage currents; and
outputting the netlist of the circuit in which the exchangable pins of the circuit are assigned to the input signals as generated the assignment as determined.

3. An automatic circuit generation program embodied on a computer-readable medium for generating circuits, said program comprising:
receiving circuit generation information required for generating a circuit, and analyzing the circuit generation information as received to generate circuit connection data and leakage current data;
receiving test vectors which are used as input signals for operating the circuit, operating a circuit with the test vectors, obtaining the state(s) of each node and the probability of each state of each node as occurs in the circuit;
receiving said circuit generation information and the state(s) of each node and the probability of each state of each node as obtained, calculating the leakage currents of the circuit, calculating the leakage currents of the circuit in the cases where input signals to exchangable pins of the circuit are exchanged, and determining an assignment of the input signals to the exchangable pins corresponding to minimum values of the leakage currents; and
outputting the netlist of the circuit in which the exchangable pins of the circuit are assigned to the input signals as generated the assignment as determined.

4. An automatic circuit generation system for generating an object circuit by the use of a cell library including logic cells, said system comprising:
a node state analyzing unit which is configured to obtain combinations of input signals to exchangable input pins of a logic cell of said cell library included in said object circuit and the probabilities of the respective combinations of the input signals;
a leakage current estimating unit which is configured to determine a combination of the input signals, with which the leakage current passing through said logic cell of said cell library included in said object circuit is minimized, with reference to information about leakage currents passing through the exchangable input pins of said logic cell of said cell library included in said object circuit; and
an output unit which is configured to output circuit information in accordance with the combination of the input signals as obtained by said leakage current estimating unit.

5. The automatic circuit generation system for generating an object circuit as claimed in claim 4 wherein the combination of the input signals is obtained by said leakage current estimating in order that the leakage current passing through said object circuit is minimized when said object circuit is inactivated in a standby state.

6. The automatic circuit generation system for generating an object circuit as claimed in claim 4 wherein the combination of the input signals is obtained by said leakage current estimating in order that the leakage current passing through said object circuit is minimized when said object circuit is operating in a normal state.

7. The automatic circuit generation system for generating an object circuit as claimed in claim 4 wherein said information of leakage currents passing through the exchangable input pins of said logic cell is obtained with reference to the circuit designs and patterns of said object circuit.

8. The automatic circuit generation system for generating an object circuit as claimed in claim 4 wherein said information of leakage currents passing through the exchangable input pins of said logic cell is obtained by measuring the actual currents passing through said object circuit.

9. An automatic circuit generation program embodied on a computer-readable medium for generating an object circuit by the use of a cell library including logic cells, said program comprising:
obtaining combinations of input signals to exchangable input pins of a logic cell of said cell library included in said object circuit and the probabilities of the respective combinations of the input signals;
determining an optimum combination of the input signals, with which the leakage current passing through said logic cell of said cell library included in said object circuit is minimized, with reference to information about leakage currents passing through the exchangable input pins of said logic cell of said cell library included in said object circuit; and
outputting circuit information in accordance with the optimum combination of the input signals as obtained with which the leakage current passing through said logic cell of said cell library included in said object circuit is minimized.

10. The automatic circuit generation program embodied on a computer-readable medium for generating an object circuit as claimed in claim 9 wherein the optimum combination of the input signals is obtained in order that the leakage current passing through said object circuit is minimized when said object circuit is inactivated in a standby state.

11. The automatic circuit generation program embodied on a computer-readable medium for generating an object circuit as claimed in claim 9 wherein said information of leakage currents passing through the exchangable input pins of said logic cell is obtained with reference to the circuit designs and patterns of said object circuit.

12. The automatic circuit generation program embodied on a computer-readable medium for generating an object circuit as claimed in claim 9 wherein said information of leakage currents passing through the exchangable input pins of said logic cell is obtained by measuring the actual currents passing through said object circuit.
